(19) United States
(12) Patent Application Publication
(10) Pub. No.: US 2006/0279291 A1
(43) Pub. Date: Dec. 14, 2006

(54) Mobile testing device

(76) Inventor: Samuel Fielding, Philadelphia, PA (US)

Correspondence Address: JOHN W. GOLDSCHMIDT, JR. ESQUIRE;DILWORTH PAXON LLP, 3200 MELLON BANK CENTER, 1735 MARKET STREET, PHILADELPHIA, PA, 19103, US

(21) Appl. No.: 11/388,462

(22) Filed: Mar. 24, 2006

Related U.S. Application Data
(60) Provisional application No. 60/664,781, filed on Mar. 24, 2005.

(51) Int. Cl. G01R 31/00

(52) U.S. Cl. 324/503

(57) ABSTRACT

A portable testing device is provided to verify the operational status, as either functional or non-functional, of lights and brake equipment on a vehicle. The mobile testing device 10 for testing a lighting and brake system of a vehicle, comprising means for coupling the mobile testing device 10 to said vehicle; a plurality of light testing devices to test the operation of the vehicle lights; and a brake testing system for initiating the vehicle's braking system and determination on the operational condition of said braking system. The mobile testing device 10 further comprising a battery for supplying power to said vehicle light during testing.

### CROSS REFERENCE TO RELATED APPLICATION

This application claims the benefit of U.S. Provisional Application Ser. No. 60/664,781, entitled “Mobile testing device 10”, filed Mar. 24, 2005, which is incorporated herein by reference in its entirety.

### BACKGROUND OF THE INVENTION

The present invention relates to a testing device for lights and brakes of a vehicle. Specifically, the present invention relates to a portable testing device used to verify the operational status, as either functional or non-functional, of lights and brake equipment on a vehicle.

All throughout the day and night, trucks transport goods, including everything from milk to automobiles, on roads and highways. Generally, trucks serve as an intermediary transportation means for goods between a variety of manufacturing facilities; rail, sea or air transportation terminals; warehouses; and stores and homes. Indeed, trucks are involved, at some point, in nearly all of the transportation of goods in their journey from a manufacturer to the end consumer of those goods. Prior to leaving a transportation facility such as a manufacturing facility, terminal or warehouse, a driver of a truck typically should check the status of the fuel and oil of the truck's engine to ensure that there is enough to transport the load of goods to a destination, such as a warehouse, store or home. The driver should also conduct an inspection of other necessary truck equipment to ensure that the braking and light systems and windshield wipers are functioning and that at least a fire extinguisher, flares, and other safety equipment are onboard the truck and in and in working order. Unfortunately, all drivers do not adhere to typical inspection procedures, and those drivers navigate roads and highways with trucks having faulty equipment. In the interest of public safety, state inspection stations have been established for the purpose of performing various types of inspections on commercial trucks, including the tractor and the trailer, to ensure that all of the equipment is properly functioning. Frequently, the inspections identify many commercial trucks being operated with equipment having mechanical and safety issues, especially brake systems, light systems and load security. One of the safety inspections that is performed on a routine basis is the testing of the trailer lights and brake systems to ensure proper function. The testing is generally time consuming and is frequently performed outdoors, in all types of weather. Accordingly, there is present need for a device that is capable of conducting an inspection test of the light and brake systems of a vehicle in a manner that is quick and easy.

### SUMMARY OF THE INVENTION

The present invention provides a device that is capable of conducting an inspection test of the light and brake systems of a vehicle in a manner that is quick and easy. The present invention comprises a mobile testing device 10 for testing a lighting and brake system of a vehicle, comprising means for coupling the mobile testing device 10 to said vehicle; a plurality of light testing devices to test the operation of the vehicle lights; and a brake testing system for initiating the vehicle's braking system and determination on the operational condition of said braking system. The mobile testing device 10 further comprises a battery for supplying power to said vehicle light during testing.

### BRIEF DESCRIPTION OF THE DRAWINGS

The accompanying drawing, which is included to provide a further understanding of the invention and are incorporated in and constitute a part of this specification, illustrate embodiments of the invention and together with this written description serve to explain the principles of the invention.

In the drawings:

FIG. 1 illustrates a mobile testing device made in accordance with the present invention.

### DETAILED DESCRIPTION OF THE PREFERRED EMBODIMENTS

Reference is now made in detail to an embodiment of the present invention, an example of which is illustrated in the accompanying drawing.

The mobile testing device 10 is preferably a battery operated mechanism designed specifically for the testing all of the various types of lights on conventional tractors and trailers and of the anti-lock braking systems (ABS) on certain tractors and trailers equipped with ABS. The mobile testing device 10 is adapted to control and test brake lights, turn signal indicators, tail lights, Department of Transportation (DOT) lights, and other marker lights. The mobile testing device 10 may be used on a temporary basis to power lights that are rendered inoperable due to blown fuses, open wiring or other problems.

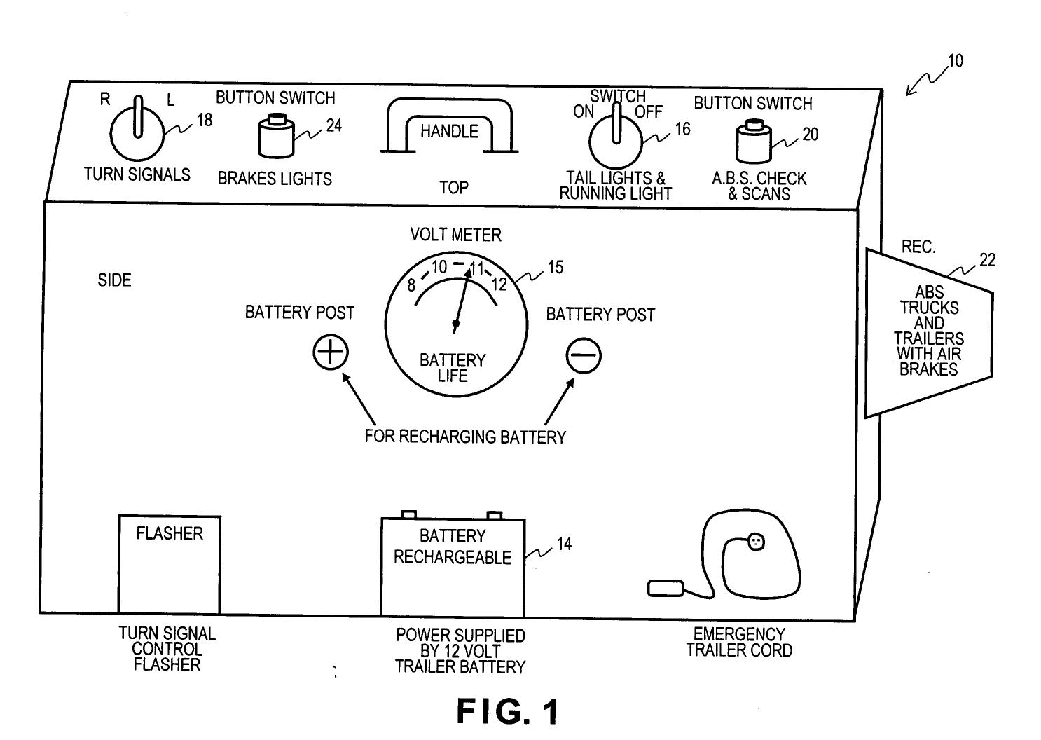

In accordance with a preferred embodiment of the present invention and as illustrated by FIG. 1, the mobile testing device 10 comprises a sturdy, plastic casing that houses a printed circuit board, a rechargeable battery 14, a plurality of flasher units, preferably two 12 volt power units, a plurality of light control switches, status indicators, a volt meter 15, and two connector cables whereby one preferably terminates with a male connector and the second preferably terminates with a female connector. Located within the housing of the mobile testing device 10, the printed circuit board provides a multiple input and output, centralized location for receiving and transmitting signal communications between a variety of elements of the mobile testing device, including the rechargeable battery 14, a plurality of flasher units, 12 volt power units, a plurality of light control switches, status indicators, a volt meter, and connector cables.

The male and female connectors enable a user to connect the mobile testing device 10 to corresponding receptacles equipped with a male connector or a female connector on a tractor or trailer. The connection between the male and female connections of the mobile testing device 10 and the corresponding receptacles equipped with a male connector or a female connector on a tractor or trailer provides the means for the mobile testing device 10 to provide power to the tractor and/or trailer systems for conducting a safety inspection. The rechargeable battery 14 of the mobile testing device 10 preferably supplies the power required to illuminate the lights of a tractor and/or trailer during the process of the safety inspection. The mobile testing device 10 also comprises switches that are adapted to test the functionality of vehicles equipped with standard brake lights and ABS brake lights.

As illustrated by FIG. 1, a two position switch 16 with “on” and “off” function is positioned on the front panel of the mobile testing device 10. The two position switch is preferably used to apply and to remove battery power from the mobile testing device 10 to the tail lights, marker lights and other lights on the tractor and/or trailer to ensure that they are properly functioning.

As illustrated by FIG. 1, a three position switch 18 with “on” and “off” function is preferably adjacently positioned to the two position switch 16 on the front panel of the mobile testing device 10. The three position switch 18 is preferably used to test the turn signal lights. The three position switch 18 is preferably used to apply and to remove battery power from the mobile testing device 10 to the turn signal lights on the tractor and/or trailer to ensure that they are properly functioning.

As illustrated by FIG. 1, a volt meter 15 is positioned on the side panel of the mobile testing device 10, adjacent to an ABS test switch 20. The volt meter 15 provides an analog indication of the battery voltage level of the battery of the mobile testing device 10. The volt meter 15 is preferably monitored occasionally to determine whether the voltage level of the recharger battery 14 is sufficient for testing purposes, and when the recharger battery 14 requires recharging.

As illustrated by FIG. 1, a button switch 24 is positioned on the front panel of the mobile testing device. The button switch 24 is preferably used to test to apply and remove battery power from the mobile testing device 10 to the brake lights on the trailer and/or trailer to ensure that they are properly functioning.

As illustrated in FIG. 1, the mobile testing device 10 also comprises a brake testing mechanism, such as an ABS testing device, or alternatively an electric brake testing device known to a skilled artisan. An ABS testing device comprises an ABS receptacle 22 that connects an ABS switch 20, which is used to initiate the brake testing procedure, to the braking system of the vehicle to be tested through a connection means. In order to operate the brake testing mechanism of the mobile testing device 10, the ABS receptacle 22 is connected to the vehicle's air lines. Once the receptacle is attached, the ABS switch 20 of the mobile testing device 10 is depressed, which in turn applies and releases air pressure to the brakes for a predetermined period of time. As those skilled in the art know, if the ABS brakes are operational, the user will observe the correct operation of the brakes. If the brakes are not operational, the mobile testing device 10 will preferably indicate the inoperability of the brakes, and the ABS light on the vehicle will light up.

The mobile testing device 10 makes it possible to easily and quickly test all lights and brakes on a truck trailer, a benefit that is fully appreciated by truck drivers and mechanics that service trucks and trailers. More importantly, the mobile testing device 10 greatly facilitates trailer safety checks and could be instrumental in improving highway safety.

The above description and the views and material depicted by the figures are for purposes of illustration only and are not intended to be, and should not be construed as, limitations on the invention. Moreover, certain modifications or alternatives may suggest themselves to those skilled in the art upon reading of this specification, all of which are intended to be within the spirit and scope of the present invention as defined in the attached claims.

What is claimed is:

1. A mobile testing device 10 for testing a lighting and brake system of a vehicle, comprising, means for coupling the mobile testing device 10 to said vehicle; a plurality of light testing devices to test the operation of the vehicle lights; and a brake testing system for initiating the vehicle's braking system and determination on the operational condition of said braking system.

2. The Mobile testing device 10 of claim 1 further comprising a battery for supplying power to said vehicle light during testing.

3. The Mobile testing device 10 of claim 2 wherein said battery provides power to said vehicle lights during an emergency.
